(19) United States
(12) Patent Application Publication
(10) Pub. No.: US 2026/0190567 A1
(43) Pub. Date: Jul. 2, 2026

(54) Display Apparatus

(71) Applicant: LG Display Co., Ltd., Seoul (KR)

(72) Inventors: MyungSub Lim, Paju-si (KR); HaeYoon Jung, Paju-si (KR); Aesun Kim, Paju-si (KR); YuRa Jeong, Paju-si (KR); Injun Lee, Paju-si (KR)

(21) Appl. No.: 19/340,582

(22) Filed: Sep. 25, 2025

(30) Foreign Application Priority Data
Dec. 27, 2024 (KR) 10-2024-0198000

(51) Int. Cl. H10H 29/39

(52) U.S. Cl. CPC H10H 29/39

(57) ABSTRACT

A display apparatus includes an electrode structure in which a first spacing distance between a first lower electrode and a second lower electrode and a second spacing distance between a first upper electrode and a second upper electrode have opposite variation patterns. This configuration can prevent abnormal short-circuiting between electrodes during the transfer of the panel electrodes and the light emitting device electrodes.

### CROSS REFERENCE TO RELATED APPLICATION

This application claims priority from Republic of Korea Patent Application No. 10-2024-0198000, filed on Dec. 27, 2024, which is hereby incorporated by reference in its entirety.

### TECHNICAL FIELD

Embodiments of the present disclosure relate to a display apparatus.

### BACKGROUND

In recent years, the size of light emitting devices has been reduced in order to implement a display apparatus with higher resolution, improved image quality, and greater stability. In a display apparatus, the light emitting device may be driven by connecting the electrodes of the light emitting device to electrodes formed on a substrate.

When the size of the light emitting device is reduced, a short circuit may occur in which the electrodes of the light emitting device and the electrodes formed on the substrate are not properly connected. For example, during a transfer process for transferring the light emitting device onto the substrate, abnormal electrical connection or short circuits between the electrodes of the light emitting device and the electrodes on the substrate may occur due to process errors.

### SUMMARY

Embodiments of the present disclosure may provide a display apparatus having an electrode structure (short-circuit prevention structure) that is robust against process errors during the manufacturing of a high-resolution display panel including a miniaturized light emitting device.

Embodiments of the present disclosure may provide a display apparatus including a short-circuit prevention structure capable of preventing abnormal short circuits (e.g., a short circuit between an anode electrode of the light emitting device and a cathode electrode on the substrate) that may occur during the panel manufacturing process for electrically connecting the electrodes (e.g., anode and cathode electrodes) of the light emitting device to the electrodes (e.g., anode and cathode electrodes) formed on the substrate of a display panel.

According to embodiments of the present disclosure, a display apparatus may be provided that includes an electrode short-circuit prevention structure capable of preventing a short-circuit phenomenon in which electrodes of a light emitting device are abnormally connected to electrodes on a substrate during a panel fabrication process, particularly during the transfer of the light emitting device onto the display panel (e.g., a short circuit between an anode electrode of the light emitting device and a cathode electrode on the substrate).

In one embodiment, a display apparatus comprises: a substrate; and a light emitting device on the substrate, the light emitting device including a first upper electrode and a second upper electrode that is spaced apart from the first upper electrode in a first horizontal direction in a plan view of the display apparatus, wherein a region in which the light emitting device is disposed comprises: a first lower electrode on the substrate, the first lower electrode overlapping the first upper electrode of the light emitting device; and a second lower electrode on the substrate and spaced apart from the first lower electrode in the first horizontal direction in the plan view, the second lower electrode overlapping the second upper electrode of the light emitting device, wherein a first spacing distance between the first lower electrode and the second lower electrode in the first horizontal direction varies depending on positions along a second horizontal direction that is different from the first horizontal direction in a plan view of the display apparatus, wherein a second spacing distance between the first upper electrode and the second upper electrode in the first horizontal direction varies depending on positions along the second horizontal direction in the plan view, and wherein a variation pattern of the first spacing distance is opposite to a variation pattern of the second spacing distance.

In one embodiment, a display apparatus comprises: a substrate; and a light emitting device on the substrate, wherein a region in which the light emitting device is disposed comprises: a first lower electrode on the substrate; a second lower electrode on the substrate and spaced apart from the first lower electrode in a first horizontal direction in a plan view of the display apparatus; a first upper electrode electrically connected to the first lower electrode; and a second upper electrode spaced apart from the first upper electrode in the first horizontal direction in the plan view, the second upper electrode electrically connected to the second lower electrode, wherein the first lower electrode and the second lower electrode are symmetrical with respect to a center between the first lower electrode and the second lower electrode in the plan view, and wherein the first upper electrode and the second upper electrode are symmetrical with respect to a center between the first upper electrode and the second upper electrode in the plan view, wherein the first lower electrode includes a first side facing the second lower electrode and the second lower electrode includes a second side facing the first lower electrode in the plan view, wherein the first upper electrode includes a third side facing the second upper electrode and the second upper electrode includes a fourth side facing the first upper electrode in the plan view, wherein the first side has a convex shape in a direction opposite to the first horizontal direction and the second side has a convex shape in the first horizontal direction in the plan view, wherein the third side has a convex shape in the first horizontal direction and the fourth side has a convex shape in a direction opposite to the first horizontal direction in the plan view.

In one embodiment, a display apparatus comprises: a substrate; a plurality of lower electrodes on the substrate, the plurality of lower electrodes including a first lower electrode and a second lower electrode that are symmetrical to each other in a plan view of the display apparatus with respect to a point between the first lower electrode and the second lower electrode; a plurality of upper electrodes on the substrate, the plurality of upper electrodes including: a first upper electrode that is electrically connected to the first lower electrode, the first upper electrode including a first portion that overlaps the first lower electrode and at least one second portion that is non-overlapping with the first lower electrode in the plan view; and a second upper electrode that is electrically connected to the second lower electrode, the second upper electrode including a first portion that overlaps the second lower electrode and at least one second portion that is non-overlapping with the second lower electrode in the plan view, wherein the first upper electrode and the second upper electrode are symmetrical to each other in the plan view with respect to a point between the first upper electrode and the second upper electrode.

According to embodiments of the present disclosure, it is possible to provide a display apparatus having a structure that is robust against process errors (i.e., a short-circuit prevention structure) during the manufacturing of a high-resolution display panel including a miniaturized light emitting device.

According to embodiments of the present disclosure, it is possible to provide a display apparatus having a short-circuit prevention structure capable of preventing abnormal short circuits (e.g., a short circuit between the anode electrode of the light emitting device and the cathode electrode on the substrate) that may occur during the process of connecting the electrodes (e.g., anode and cathode electrodes) of the light emitting device to the electrodes (e.g., anode and cathode electrodes) formed on the substrate of a display panel.

According to embodiments of the present disclosure, a display apparatus may be provided that includes an electrode short-circuit prevention structure capable of preventing a short-circuit phenomenon in which electrodes of a light emitting device are abnormally connected to electrodes on a substrate during a panel fabrication process, particularly during the transfer of the light emitting device onto the display panel (e.g., a short circuit occurring between an anode electrode of the light emitting device and a cathode electrode on the substrate).

According to embodiments of the present disclosure, by reducing defects caused by process errors during the manufacture of a display panel, it is possible to enable process optimization and provide a display apparatus capable of improving panel yield and reducing greenhouse gas emissions.

### BRIEF DESCRIPTION OF THE DRAWINGS

FIG. 1 is a schematic view illustrating a configuration of a display apparatus according to embodiments of the present disclosure.

FIG. 2 is a circuit diagram of a sub-pixel SP according to embodiments of the present disclosure.

FIG. 3 is a cross-sectional view showing that electrodes of the display panel and the light emitting device are electrically connected without short circuits due to process errors according to embodiments of the present disclosure.

FIG. 4 is another cross-sectional view illustrating that electrodes of the display panel and the light emitting device are electrically connected without short circuits due to process errors according to embodiments of the present disclosure.

FIG. 5 is a plan view illustrating the electrical connection of the electrodes of the display panel and the light emitting device without short circuits caused by process errors according to embodiments of the present disclosure.

FIG. 6 is a cross-sectional view illustrating a short circuit caused by a process error between the electrodes of the display panel and the light emitting device.

FIG. 7 is another cross-sectional view illustrating a short circuit caused by a process error between the electrodes of the display panel and the light emitting device.

FIG. 8 is a plan view illustrating a short circuit caused by a process error between the electrodes of the display panel and the light emitting device.

FIG. 9 and FIG. 10 are diagrams illustrating a short-circuit prevention electrode structure according to embodiments of the present disclosure.

FIG. 11 and FIG. 12 are additional diagrams illustrating a short-circuit prevention electrode structure according to embodiments of the present disclosure.

FIG. 13 and FIG. 14 are further diagrams illustrating a short-circuit prevention electrode structure according to embodiments of the present disclosure.

FIG. 15 and FIG. 16 are other diagrams illustrating a short-circuit prevention electrode structure according to embodiments of the present disclosure.

FIG. 17 and FIG. 18 are still further diagrams illustrating a short-circuit prevention electrode structure according to embodiments of the present disclosure.

### DETAILED DESCRIPTION

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Various embodiments of the present specification will be described in detail with reference to the accompanying drawings.

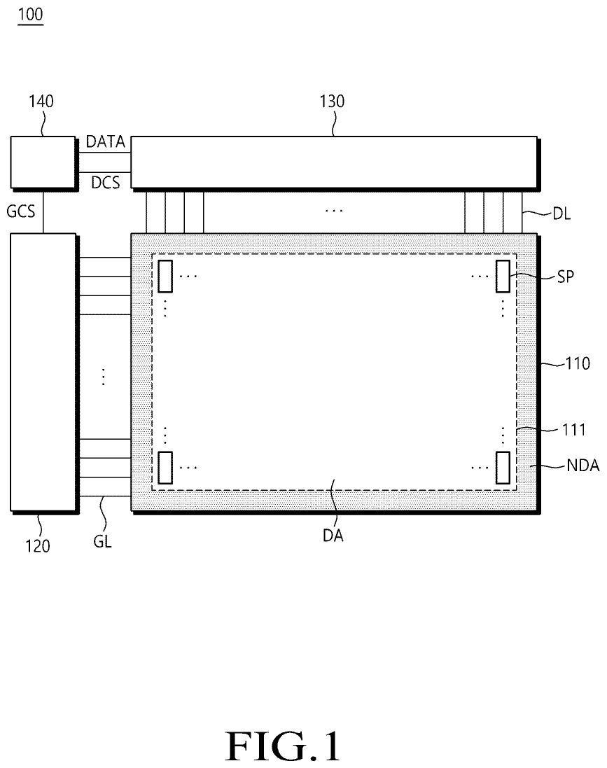

FIG. 1 illustrates a schematic configuration of a display apparatus according to embodiments of the present disclosure.

Referring to FIG. 1, a display apparatus 100 may include a display panel 110, a data driving circuit 130, a gate driving circuit 120, and a controller 140.

The display panel 110 may include a display area DA in which an image is displayed and a non-display area NDA in which no image is displayed.

The display panel 110 may include a substrate 111, a plurality of sub-pixels SP disposed on the substrate 111, and various signal lines for driving the plurality of sub-pixels SP. The plurality of sub-pixels SP may be disposed in the display area DA.

The signal lines may include a plurality of data lines DL that transmit data signals (also referred to as data voltages or image signals) and a plurality of gate lines GL that transmit gate signals (also referred to as scan signals). The plurality of data lines DL and the plurality of gate lines GL may intersect each other.

Each of the plurality of data lines DL may extend in a first direction, and each of the plurality of gate lines GL may extend in a second direction. Here, the first direction may be a column direction, and the second direction may be a row direction. Alternatively, the first direction may be a row direction, and the second direction may be a column direction. For ease of explanation, it is assumed below that the data lines DL are arranged in the column direction and the gate lines GL are arranged in the row direction.

The data driving circuit 130 may be a circuit that drives the data lines DL and may output data signals to the data lines DL. The gate driving circuit 120 may be a circuit that drives the gate lines GL and may output gate signals to the gate lines GL. The controller 140 may be an apparatus that controls the data driving circuit 130 and the gate driving circuit 120 and may control the driving timing of the data lines DL and the gate lines GL.

The controller 140 may supply a data driving control signal DCS to the data driving circuit 130 to control the data driving circuit 130 and may supply a gate driving control signal GCS to the gate driving circuit 120 to control the gate driving circuit 120.

The data driving circuit 130 may supply data signals DATA to the plurality of data lines DL according to timing control by the controller 140. The data driving circuit 130 may receive image data in digital form from the controller 140, convert the received image data into analog data signals, and output the analog data signals to the plurality of data lines DL.

The gate driving circuit 120 may supply gate signals to the plurality of gate lines GL under the timing control of the controller 140. The gate driving circuit 120 may receive various gate driving control signals (e.g., start signal, reset signal, etc.) along with a first gate voltage corresponding to a turn-on level and a second gate voltage corresponding to a turn-off level, generate gate signals, and supply the generated gate signals to the plurality of gate lines GL.

For example, the data driving circuit 130 may be connected to the display panel 110 using a Tape Automated Bonding (TAB) method, connected to a bonding pad of the display panel 110 using a Chip On Glass (COG) or Chip On Panel (COP) method, or implemented using a Chip On Film (COF) method and connected to the display panel 110. Hereinafter, for ease of explanation, it is assumed that the data driving circuit 130 is connected to the display panel 110 by the Chip On Film (COF) method.

The gate driving circuit 120 may be connected to the display panel 110 using a Tape Automated Bonding (TAB) method, connected to a bonding pad of the display panel 110 using a Chip On Glass (COG) or Chip On Panel (COP) method, or connected to the display panel 110 using a Chip On Film (COF) method. Alternatively, the gate driving circuit 120 may be disposed in a non-active area or an active area of the display panel 110 in a Gate In Panel (GIP) configuration.

At least one of the data driving circuit 130 and the gate driving circuit 120 may be disposed in the active area of the display panel 110. For example, at least one of the data driving circuit 130 and the gate driving circuit 120 may be disposed so as not to overlap the sub-pixels SP, or all or part of at least one of the data driving circuit 130 and the gate driving circuit 120 may be disposed to overlap the sub-pixels SP.

The data driving circuit 130 may be connected to one side (e.g., an upper side or a lower side) of the display panel 110. Depending on the driving method or panel design scheme, the data driving circuit 130 may be connected to both sides (e.g., upper and lower sides) of the display panel 110 or to two or more of the four sides of the display panel 110.

The gate driving circuit 120 may be connected to one side (e.g., a left side or a right side) of the display panel 110. Depending on the driving method or panel design scheme, the gate driving circuit 120 may be connected to both sides (e.g., left and right sides) of the display panel 110 or to two or more of the four sides of the display panel 110.

The controller 140 may be implemented as a component separate from the data driving circuit 130 or may be integrated with the data driving circuit 130 into a single integrated circuit. The controller 140 may be a timing controller used in general display technologies, a control device including a timing controller and performing additional control functions, a control device other than a timing controller, or a circuit within a control device. The controller 140 may be implemented using various circuits or electronic components such as an integrated circuit (IC), a field programmable gate array (FPGA), an application-specific integrated circuit (ASIC), or a processor.

The controller 140 may be mounted on a printed circuit board or a flexible printed circuit and may be electrically connected to the data driving circuit 130 and the gate driving circuit 120 through the printed circuit board or the flexible printed circuit. The controller 140 may transmit and receive signals to and from the data driving circuit 130 via one or more predetermined interfaces. For example, the interface may include a Low Voltage Differential Signaling (LVDS) interface, an Embedded Panel Interface (EPI), or a Serial Peripheral Interface (SPI).

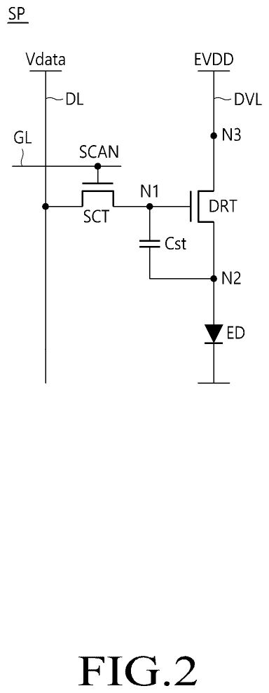

FIG. 2 is a circuit diagram of sub-pixels SP arranged in the display apparatus 100 according to embodiments of the present disclosure.

Referring to FIG. 2, a sub-pixel SP disposed in the display panel 110 of the display apparatus 100 according to embodiments of the present disclosure may include one or more transistors and a capacitor, and may include a light emitting device ED. For example, the sub-pixel SP may include a driving transistor DRT, a scan transistor SCT, a storage capacitor Cst, and the light emitting device ED.

The driving transistor DRT may be a transistor for driving the light emitting device ED and may include a first node N1, a second node N2, and a third node N3.

The first node N1 of the driving transistor DRT may be a gate node of the driving transistor DRT and may be electrically connected to a source node or a drain node of the scan transistor SCT. The second node N2 of the driving transistor DRT may be a source node or a drain node of the driving transistor DRT and may be electrically connected to a pixel electrode of the light emitting device ED. The third node N3 of the driving transistor DRT may be electrically connected to a driving voltage line DVL that supplies a driving voltage EVDD.

The scan transistor SCT may be controlled by a scan pulse SCAN, which is a type of gate signal, and may be connected between a first node N1 of the driving transistor DRT and a data line DL. In other words, the scan transistor SCT may be turned on or off according to the scan pulse SCAN supplied from a scan line SCL, which is a type of gate line GL, and may control the connection between the data line DL and the first node N1 of the driving transistor DRT.

The scan transistor SCT may be turned on by the scan pulse SCAN having a turn-on level voltage, and may transfer a data signal Vdata supplied from the data line DL to the first node N1 of the driving transistor DRT.

When the scan transistor SCT is an n-type transistor, the turn-on level voltage of the scan pulse SCAN may be a high-level voltage. When the scan transistor SCT is a p-type transistor, the turn-on level voltage of the scan pulse SCAN may be a low-level voltage.

A storage capacitor Cst may be connected between the first node N1 and the second node N2 of the driving transistor DRT. The storage capacitor Cst may be charged with an amount of charge corresponding to a voltage difference between both terminals and may maintain the voltage difference for a predetermined frame period. Accordingly, the corresponding sub-pixel SP may emit light during the predetermined frame period.

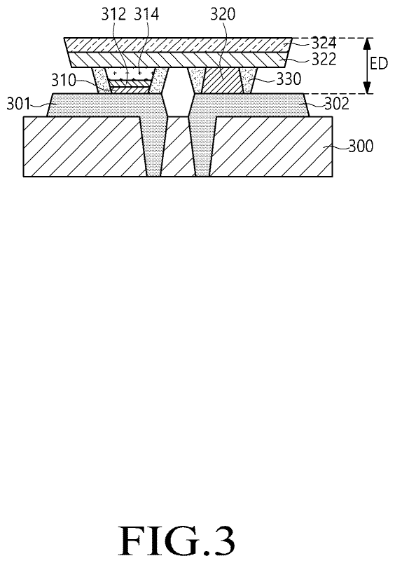

FIG. 3 is a cross-sectional view illustrating an electrical connection between electrodes of the display panel 110 and electrodes of the light emitting device without short-circuiting due to a process error according to embodiments of the present disclosure.

Referring to FIG. 3, the light emitting device ED according to embodiments of the present disclosure may include a first electrode 310, a first semiconductor layer 312, a light emitting layer 314, a second semiconductor layer 322, and a second electrode 320.

The first electrode 310 and the second electrode 320 may be disposed with a predetermined spacing therebetween. For example, the first electrode 310 may be an anode electrode, and the second electrode 320 may be a cathode electrode. Alternatively, the first electrode 310 may be a cathode electrode, and the second electrode 320 may be an anode electrode.

The first semiconductor layer 312 may be disposed on the first electrode 310.

The light emitting layer 314 may be disposed on the first semiconductor layer 312.

The second semiconductor layer 322 may be disposed on the light emitting layer 314 and the second electrode 320.

The first semiconductor layer 312 may be formed beneath at least one side of the second semiconductor layer 322, and may expose at least a portion of the opposite side of the second semiconductor layer 322.

The light emitting layer 314 may be disposed between the first semiconductor layer 312 and the second semiconductor layer 322.

The first electrode 310 may be formed under the first semiconductor layer 312 and may be electrically connected to the first semiconductor layer 312. The second electrode 320 may be formed under the opposite side of the second semiconductor layer 322 and may be electrically connected to the second semiconductor layer 322.

The first semiconductor layer 312 may be implemented as a p-type semiconductor layer.

The second semiconductor layer 322 may be implemented as an n-type semiconductor layer.

The light emitting layer 314 may be a layer that emits light by recombination of holes injected through the first semiconductor layer 312 and electrons injected through the second semiconductor layer 322, based on a bandgap difference of the material forming the light emitting layer 314.

The light emitting device ED may further include an insulating film 330 for protecting the elements of the light emitting device ED.

The insulating film 330 may be disposed on a side surface of the first electrode 310 and a side surface of the second electrode 320.

The insulating film 330 may also be disposed on the side surfaces of the first semiconductor layer 312 and the light emitting layer 314, but is not limited thereto. For example, the insulating film 330 may further be disposed on the side surfaces of the second semiconductor layer 322 and a third semiconductor layer 324.

The insulating film 330 may include silicon and may be, for example, one selected from a silicon oxide film (SiOx), a silicon nitride film (SiNx), or a stacked structure thereof.

Referring to FIG. 3, the light emitting device ED according to embodiments of the present disclosure may further include a third semiconductor layer 324 disposed on the second semiconductor layer 322. For example, the third semiconductor layer 324 may include an undoped semiconductor material.

The light emitting device ED according to embodiments of the present disclosure may be disposed on an insulating layer 300. To this end, the display panel 110 according to embodiments of the present disclosure may include a first driving electrode 301 and a second driving electrode 302, each disposed on the insulating layer 300.

The first driving electrode 301 may be electrically connected to the first electrode 310 of the light emitting device ED through an electrode connection layer (not shown) located between the first driving electrode 301 and the first electrode 310. The second driving electrode 302 may be electrically connected to the second electrode 320 of the light emitting device ED through an electrode connection layer (not shown) located between the second driving electrode 302 and the second electrode 320. For example, the first driving electrode 301 may be an anode electrode, and the second driving electrode 302 may be a cathode electrode. Alternatively, the first driving electrode 301 may be a cathode electrode, and the second driving electrode 302 may be an anode electrode. The electrode connection layer (not shown) may include a metal component or a carbon component so as to electrically connect the first driving electrode 301 to the first electrode 310, and the second driving electrode 302 to the second electrode 320.

During the panel manufacturing process, if no short-circuit occurs due to process error during the light emitting device transfer step, which is performed after the first driving electrode 301 and the second driving electrode 302 are formed without short-circuiting, the first electrode 310 of the light emitting device ED may be positioned on the first driving electrode 301, and the second electrode 320 of the light emitting device ED may be positioned on the second driving electrode 302. Accordingly, the first electrode 310 of the light emitting device ED may be electrically connected to the first driving electrode 301, and the second electrode 320 of the light emitting device ED may be electrically connected to the second driving electrode 302.

In addition, when no short-circuit occurs due to process error, the first electrode 310 of the light emitting device ED may be electrically connected to the first driving electrode 301 but not electrically connected to the second driving electrode 302. The second electrode 320 of the light emitting device ED may be electrically connected to the second driving electrode 302 but not electrically connected to the first driving electrode 301. That is, when no short-circuit occurs due to a transfer process error, a short between the electrodes does not occur.

The light emitting device ED illustrated in FIG. 3 according to embodiments of the present disclosure may be of a flip-chip type but is not limited thereto and may alternatively be a lateral chip type.

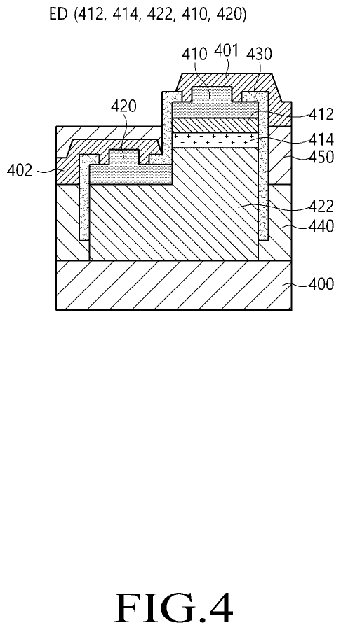

FIG. 4 is a cross-sectional view illustrating an electrical connection between electrodes of the display panel 110 and electrodes of the light emitting device without short-circuiting due to a process error according to one embodiment. Here, “electrically connected without short-circuit” may mean that the first electrode of the light emitting device is electrically connected to the first driving electrode but not to the second driving electrode, and the second electrode of the light emitting device is electrically connected to the second driving electrode but not to the first driving electrode. That is, this may correspond to a state in which no short-circuit occurs between the first and second electrodes. Meanwhile, the dimensions of components may be interpreted as including an error range caused by various factors such as process conditions, internal or external impact, or noise.

Referring to FIG. 4, the light emitting device ED according to embodiments of the present disclosure may be disposed on a first insulating layer 400 of the display panel 110.

For example, the first insulating layer 400 may be an adhesive layer.

The light emitting device ED may include a first semiconductor layer 412, a light emitting layer 414, a second semiconductor layer 422, a first electrode 410, and a second electrode 420.

The second semiconductor layer 422 may be disposed on the first insulating layer 400.

The light emitting layer 414 may be disposed on at least one side of the second semiconductor layer 422.

The first semiconductor layer 412 may be disposed on the light emitting layer 414.

The light emitting layer 414 may be disposed between the first semiconductor layer 412 and the second semiconductor layer 422.

The first electrode 410 may be formed on the upper portion of the first semiconductor layer 412 and may be electrically connected to the first semiconductor layer 412. The second electrode 420 may be formed on the opposite side of the second semiconductor layer 422 and may be electrically connected to the second semiconductor layer 422.

The first electrode 410 and the second electrode 420 may be disposed with a spacing therebetween. For example, the first electrode 410 may be an anode electrode, and the second electrode 420 may be a cathode electrode. Alternatively, the first electrode 410 may be a cathode electrode, and the second electrode 420 may be an anode electrode.

The first semiconductor layer 412 may be implemented as a p-type semiconductor layer.

The second semiconductor layer 422 may be implemented as an n-type semiconductor layer.

The light emitting layer 414 may be a layer that emits light through recombination of holes injected through the first semiconductor layer 412 and electrons injected through the second semiconductor layer 422, based on a bandgap difference of a material forming the light emitting layer 414.

The light emitting device ED may further include an insulating film 430 for protecting components of the light emitting device ED.

The insulating film 430 may be disposed on a portion of an upper surface and a side surface of the first electrode 410 and on a portion of an upper surface and a side surface of the second electrode 420.

The insulating film 430 may also be disposed on side surfaces of the first semiconductor layer 412, the light emitting layer 414, and the second semiconductor layer 422.

For example, the insulating film 430 may be formed of either a silicon oxide film (SiOx) or a silicon nitride film (SiNx), or may have a stacked structure thereof.

Referring to FIG. 4, the display panel 110 according to embodiments of the present disclosure may further include a second insulating layer 440 formed on the first insulating layer 400 and a third insulating layer 450 formed on the second insulating layer 440.

The light emitting device ED according to embodiments of the present disclosure may be disposed on the first insulating layer 400. To this end, the display panel 110 according to embodiments of the present disclosure may include a first driving electrode 401 disposed on the third insulating layer 450 and a second driving electrode 402 disposed on the second insulating layer 440.

The first driving electrode 401 may be electrically connected to the first electrode 410 of the light emitting device ED. The second driving electrode 402 may be electrically connected to the second electrode 420 of the light emitting device ED. For example, the first driving electrode 401 may be an anode electrode, and the second driving electrode 402 may be a cathode electrode. Alternatively, the first driving electrode 401 may be a cathode electrode, and the second driving electrode 402 may be an anode electrode.

During the panel manufacturing process, if no error occurs when forming the first driving electrode 401 and the second driving electrode 402 after the light emitting device ED is disposed on the first insulating layer 400 without short-circuiting due to process error, the first driving electrode 401 may be positioned on the first electrode 410 of the light emitting device ED, and the second driving electrode 402 may be positioned on the second electrode 420 of the light emitting device ED. Accordingly, the first driving electrode 401 may be electrically connected to the first electrode 410 of the light emitting device ED, and the second driving electrode 402 may be electrically connected to the second electrode 420 of the light emitting device ED.

In addition, when no short-circuit occurs due to process error, the first electrode 410 of the light emitting device ED may be electrically connected to the first driving electrode 401, but not electrically connected to the second driving electrode 402. The second electrode 420 of the light emitting device ED may be electrically connected to the second driving electrode 402, but not electrically connected to the first driving electrode 401. That is, when no short-circuit occurs due to a transfer process error, a short between the electrodes does not occur.

The light emitting device ED according to the embodiment illustrated in FIG. 4 may be a lateral chip type.

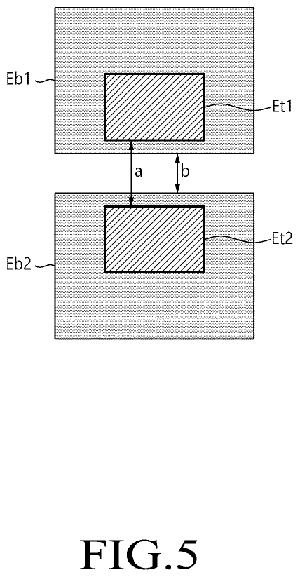

FIG. 5 is a plan view illustrating that a first upper electrode Et1 and a second upper electrode Et2 are electrically connected to a first lower electrode Eb1 and a second lower electrode Eb2, respectively, without short-circuiting due to a process error during a panel manufacturing process for connecting the electrodes of the display panel 110 to the electrodes of the light emitting device ED as shown in FIG. 3 or FIG. 4 according to one embodiment.

For example, the first upper electrode Et1 and the second upper electrode Et2 in FIG. 5 may be electrodes (e.g., anode electrode, cathode electrode) of the light emitting device ED. The first lower electrode Eb1 and the second lower electrode Eb2 in FIG. 5 may be electrodes formed on the substrate 111 that are connected to the electrodes of the light emitting device ED. For example, the first upper electrode Et1 and the second upper electrode Et2 in FIG. 5 may correspond to the first electrode 310 and the second electrode 320 of the light emitting device ED in FIG. 3. The first lower electrode Eb1 and the second lower electrode Eb2 in FIG. 5 may correspond to the first driving electrode 301 and the second driving electrode 302 of FIG. 3.

In another example, the first lower electrode Eb1 and the second lower electrode Eb2 in FIG. 5 may be the electrodes (e.g., anode electrode, cathode electrode) of the light emitting device ED, and the first upper electrode Et1 and the second upper electrode Et2 in FIG. 5 may be electrodes formed on the substrate 111 and connected to the electrodes of the light emitting device ED. For example, the first lower electrode Eb1 and the second lower electrode Eb2 in FIG. 5 may correspond to the first electrode 410 and the second electrode 420 of the light emitting device ED in FIG. 4. The first upper electrode Et1 and the second upper electrode Et2 in FIG. 5 may correspond to the first driving electrode 401 and the second driving electrode 402 in FIG. 4.

A spacing between the first upper electrode Et1 and the second upper electrode Et2 may be a first distance a, and a spacing between the first lower electrode Eb1 and the second lower electrode Eb2 may be a second distance b.

The first distance a, which is the distance between the first upper electrode Et1 and the second upper electrode Et2 in a first horizontal direction, may correspond to a second spacing distance, and the second spacing distance may vary depending on positions in a second horizontal direction. The distance between the first lower electrode Eb1 and the second lower electrode Eb2 in the first horizontal direction, which may be the second distance b, may correspond to a first spacing distance, and the first spacing distance may also vary depending on positions in the second horizontal direction that is different from the first horizontal direction.

For example, the first upper electrode Et1, the second upper electrode Et2, the first lower electrode Eb1, and the second lower electrode Eb2 may each have a rectangular shape.

In the following description, the first upper electrode Et1 and the second upper electrode Et2 may be electrodes of the light emitting device ED, or electrodes formed on the substrate 111 and connected to the electrodes of the light emitting device ED. In addition, the first lower electrode Eb1 and the second lower electrode Eb2 may be electrodes formed on the substrate 111 and connected to the electrodes of the light emitting device ED, or may be the electrodes of the light emitting device ED themselves.

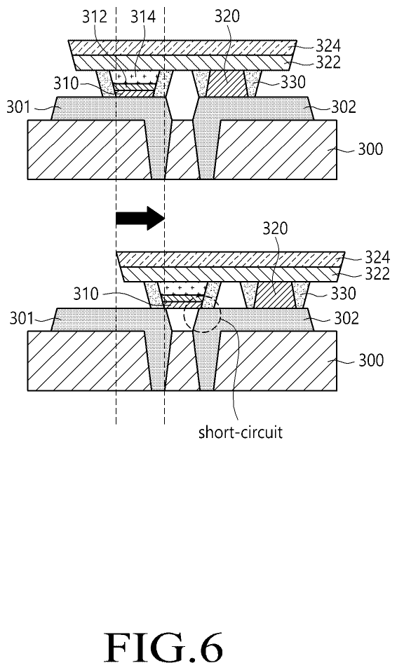

FIG. 6 is a cross-sectional view illustrating a short-circuit between the electrodes of the display panel 110 and the electrodes of the light emitting device ED in FIG. 3 due to a process error.

For example, during the transfer of the light emitting device ED onto the first driving electrode 301 and the second driving electrode 302 of the display panel 110, a process error may occur, resulting in a short-circuit between the first driving electrode 301 and the second driving electrode 302 of the display panel 110 and the first electrode 310 and the second electrode 320 of the light emitting device ED.

In another example, when a process error occurs during the formation of the first driving electrode and the second driving electrode on the insulating layer, a short-circuit may occur between the first driving electrode 301 and the second driving electrode 302 of the display panel 110 and the first electrode 310 and the second electrode 320 of the light emitting device ED.

The first electrode 310 may be electrically connected to both the first driving electrode 301 and the second driving electrode 302, resulting in a short-circuit.

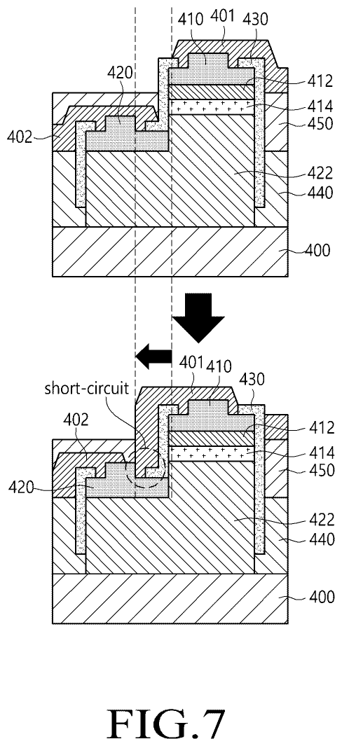

FIG. 7 is a cross-sectional view illustrating a short circuit caused by a process error between the electrodes of the display panel 110 and the electrodes of the light emitting device ED shown in FIG. 4.

For example, a short circuit may occur between the first driving electrode 401 and the second driving electrode 402 of the display panel 110 and the first electrode 410 and the second electrode 420 of the light emitting device ED due to a process error during the transfer of the light emitting device ED onto the first insulating layer 400.

In another example, a short circuit may occur between the first driving electrode 401 and the second driving electrode 402 of the display panel 110 and the first electrode 410 and the second electrode 420 of the light emitting device ED when a process error occurs during formation of the first driving electrode 401 and the second driving electrode 402.

The first driving electrode 401 may be electrically connected to both the first electrode 410 and the second electrode 420, causing a short circuit.

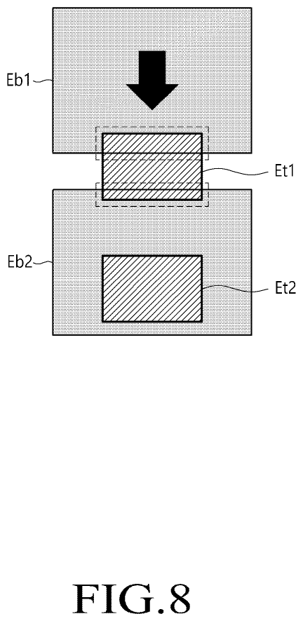

FIG. 8 is a plan view illustrating a short circuit caused by a process error between the electrodes of the display panel 110 and the electrodes of the light emitting device ED shown in FIG. 3 or FIG. 4.

Referring to FIG. 8, a short circuit may occur between the first lower electrode Eb1 and the second lower electrode Eb2 and the first upper electrode Et1 and the second upper electrode Et2 due to a process error during a transfer process that connects the first lower electrode Eb1 and the second lower electrode Eb2 with the first upper electrode Et1 and the second upper electrode Et2.

The first upper electrode Et1 may overlap and connect to both the first lower electrode Eb1 and the second lower electrode Eb2, thereby causing a short circuit.

As the size of the light emitting device becomes smaller, the electrodes of the light emitting device must also become smaller. However, in order to connect the electrodes of the panel to the electrodes of the light emitting device, the size of the light emitting device electrodes must be secured to a certain level. At the same time, a problem arises in that short circuits may occur due to process errors during the connection of the panel electrodes and the light emitting device electrodes. Accordingly, the inventors of the present disclosure have developed an electrode structure capable of preventing short circuits when connecting the panel electrodes and the light emitting device electrodes.

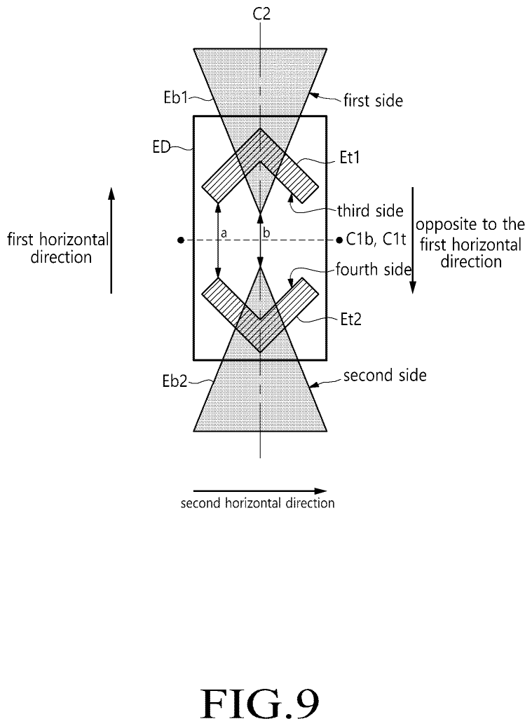

Hereinafter, a short-circuit prevention electrode structure included in the display apparatus 100 according to embodiments of the present disclosure will be described with reference to FIG. 9 to FIG. 18. For convenience of description, it is assumed that the light emitting device ED is a flip chip type as illustrated in FIG. 3. However, the present disclosure is not limited thereto.

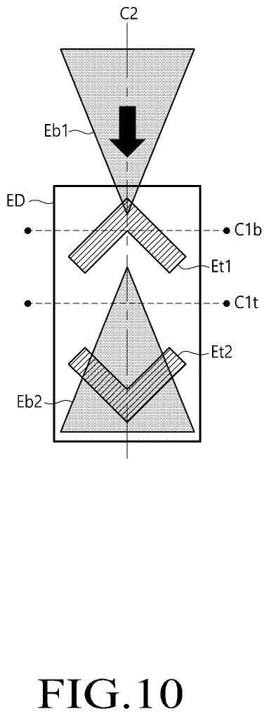

FIG. 9 and FIG. 10 are plan views illustrating a short-circuit prevention electrode structure of the display apparatus 100 according to embodiments of the present disclosure. FIG. 9 shows a case without a process error, and FIG. 10 shows a case with a process error.

Referring to FIG. 9 and FIG. 10, in the display apparatus 100 according to embodiments of the present disclosure, the display panel 110 may include a light emitting device ED disposed on a substrate. A region in which the light emitting device ED is disposed may include a first lower electrode Eb1, a second lower electrode Eb2, a first upper electrode Et1, and a second upper electrode Et2.

The second lower electrode Eb2 may be spaced apart from the first lower electrode Eb1 in a first horizontal direction and may be electrically connected to the second upper electrode Et2. The first lower electrode Eb1 may be electrically connected to the first upper electrode Et1. The second upper electrode Et2 may be spaced apart from the first upper electrode Et1 in the first horizontal direction and may be electrically connected to the second lower electrode Eb2.

The first lower electrode Eb1 may have an inverted triangular shape, and the second lower electrode Eb2 may have a triangular shape symmetrical to the first lower electrode Eb1.

The first upper electrode Et1 may have a shape rotated 45 degrees clockwise from an uppercase “L,” and the second upper electrode Et2 may have a shape symmetrical to the first upper electrode Et1. Thus, the first upper electrode Et1 and the second upper electrode Et2 have a “V” shape in the plan view as shown in FIGS. 9 and 10.

A spacing between the closest points between the first upper electrode Et1 and the second upper electrode Et2 may be a first distance a, and a spacing between the closest points between the first lower electrode Eb1 and the second lower electrode Eb2 may be a second distance b.

The first and second lower electrodes Eb1 and Eb2 may be symmetrical with respect to a center C1b between them in a plan view of the display apparatus, and the first and second upper electrodes Et1 and Et2 may be symmetrical with respect to a center C1t (e between them in the plan view.

The first distance a between the first upper electrode Et1 and the second upper electrode Et2 in the first horizontal direction may be referred to as a second spacing distance, which may vary depending on positions in a second horizontal direction. The second distance b between the first lower electrode Eb1 and the second lower electrode Eb2 in the first horizontal direction may be referred to as a first spacing distance, which may also vary depending on positions in the second horizontal direction different from the first horizontal direction.

Referring to FIG. 9 and FIG. 10, a variation pattern of the first spacing distance between the first lower electrode Eb1 and the second lower electrode Eb2 and a variation pattern of the second spacing distance between the first upper electrode Et1 and the second upper electrode Et2 may be opposite to each other.

The first spacing distance between the first lower electrode Eb1 and the second lower electrode Eb2 in the first horizontal direction may decrease toward a central position C2 in the second horizontal direction.

The second spacing distance between the first upper electrode Et1 and the second upper electrode Et2 in the first horizontal direction may increase toward the central position C2 in the second horizontal direction. Thus, the variation pattern of the first spacing distance increases as the variation pattern of the second spacing distance decreases and vice versa.

Referring to FIG. 9 and FIG. 10, the first lower electrode Eb1 may have a first point closest to the second lower electrode Eb2, and the second lower electrode Eb2 may have a second point closest to the first lower electrode Eb1.

The first lower electrode Eb1 may be symmetrical with respect to an imaginary line C2 connecting the first and second points, and the second lower electrode Eb2 may also be symmetrical with respect to the same imaginary line C2.

The first upper electrode Et1 may have a third point farthest from the second upper electrode Et2, and the second upper electrode Et2 may have a fourth point farthest from the first upper electrode Et1.

The first upper electrode Et1 may be symmetrical with respect to an imaginary line C2 connecting the third and fourth points, and the second upper electrode Et2 may also be symmetrical with respect to the same imaginary line C2.

According to an embodiment of the present disclosure, the second upper electrode Et2 and the second lower electrode Eb2 may include: an overlapping region in which the second upper electrode Et2 and the second lower electrode Eb2 overlap each other; a first non-overlapping region at a first side of the overlapping region where the second upper electrode Et2 and the second lower electrode Eb2 do not overlap (e.g., non-overlapping); and a second non-overlapping region at a second side of the overlapping region that is located opposite to the first side of the overlapping region where the second upper electrode Et2 and the second lower electrode Eb2 do not overlap. The first non-overlapping region may have a first length in a second horizontal direction different from the first horizontal direction, and the second non-overlapping region may have a second length in the second horizontal direction different from the first length.

In another example, the first upper electrode Et1 and the first lower electrode Eb1 may include: an overlapping region where the first upper electrode Et1 and the first lower electrode Eb1 overlap; a first non-overlapping region at a first side of the overlapping region where the first upper electrode Et1 and the first lower electrode Eb1 do not overlap (e.g., non-overlapping); and a second non-overlapping region at a second side of the overlappign region that is opposite the first side where the first upper electrode Et1 and the first lower electrode Eb1 also do not overlap. The first non-overlapping region may have a first length in the second horizontal direction that is different from the first horizontal direction, and the second non-overlapping region may have a second length in the second horizontal direction that is different from the first length.

Even if an error occurs during the process of connecting the first upper electrode Et1 and the second upper electrode Et2 to the first lower electrode Eb1 and the second lower electrode Eb2, a short circuit may not occur between the first lower electrode Eb1 and the first upper electrode Et1, and between the second lower electrode Eb2 and the second upper electrode Et2.

Referring to FIG. 9 and FIG. 10, the first side may have a convex shape in a direction opposite to the first horizontal direction, the second side may have a convex shape in the first horizontal direction, the third side may have a convex shape in the first horizontal direction, and the fourth side may have a convex shape in a direction opposite to the first horizontal direction.

Referring again to FIG. 9 and FIG. 10, the first lower electrode Eb1 may have a first side facing the second lower electrode Eb2, and the second lower electrode Eb2 may have a second side facing the first lower electrode Eb1. Each of the first and second sides may include a bent surface at one or more points.

The first upper electrode Et1 may have a third side facing the second upper electrode Et2, and the second upper electrode Et2 may have a fourth side facing the first upper electrode Et1. Each of the third and fourth sides may include a bent surface at one or more points.

Due to the short-circuit prevention electrode structure shown in FIG. 9, even if an error occurs as shown in FIG. 10 during the process of connecting the first upper electrode Et1 and the second upper electrode Et2 to the corresponding first lower electrode Eb1 and second lower electrode Eb2, a short circuit may not occur between the first lower electrode Eb1 and the first upper electrode Et1, and between the second lower electrode Eb2 and the second upper electrode Et2.

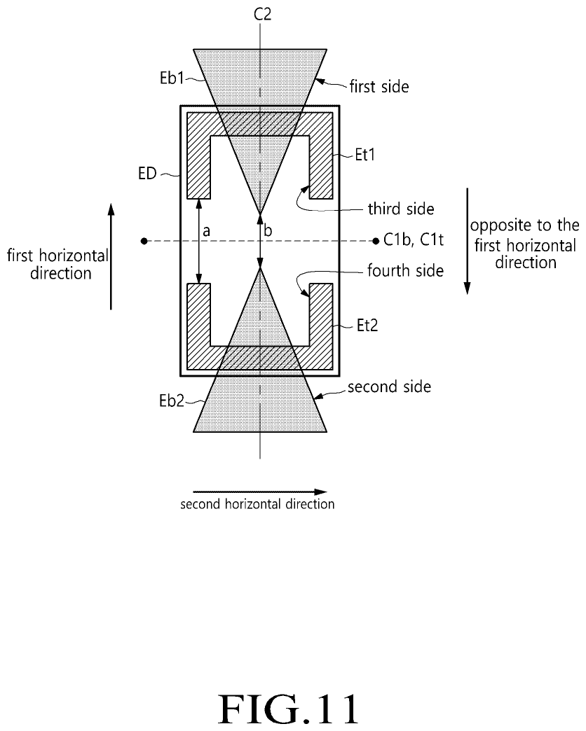

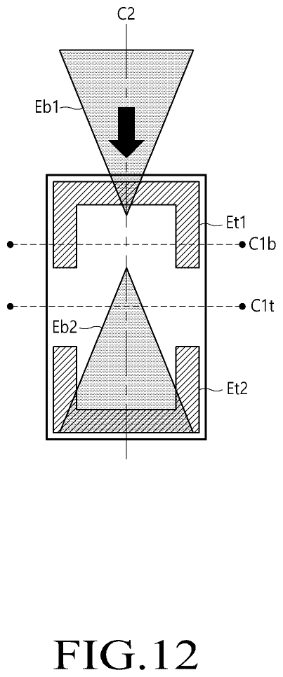

FIG. 11 and FIG. 12 are other plan views illustrating a short-circuit prevention electrode structure of the display apparatus 100 according to embodiments of the present disclosure. FIG. 11 illustrates a case where no short circuit occurs due to a process error, and FIG. 12 illustrates a case where a short circuit occurs due to a process error.

Referring to FIG. 11 and FIG. 12, in the display apparatus 100 according to embodiments of the present disclosure, the display panel 110 may include a light emitting device ED disposed on a substrate. A region in which the light emitting device ED is disposed may include a first lower electrode Eb1, a second lower electrode Eb2, a first upper electrode Et1, and a second upper electrode Et2.

The second lower electrode Eb2 may be spaced apart from the first lower electrode Eb1 in a first horizontal direction and may be electrically connected to the second upper electrode Et2. The first lower electrode Eb1 may be electrically connected to the first upper electrode Et1. The second upper electrode Et2 may be spaced apart from the first upper electrode Et1 in the first horizontal direction and may be electrically connected to the second lower electrode Eb2.

Referring again to FIG. 11 and FIG. 12, the first lower electrode Eb1 may have an inverted triangular shape, and the second lower electrode Eb2 may have a triangular shape symmetrical to the first upper electrode Et1.

The first upper electrode Et1 may have a shape resembling an uppercase Greek letter pi (Π), and the second upper electrode Et2 may have a shape symmetrical to the first upper electrode Et1. The first upper electrode Et1 and the second upper electrode ET2 each have a first horizontal portion extending in the second horizontal direction and a first vertical portion extending from a first end of the first horizontal portion in the first horizontal direction and a second vertical portion extending from a second end of the first horizontal portion in the first horizontal direction in the plan view.

A spacing between the first upper electrode Et1 and the second upper electrode Et2 may be defined as a first distance a, and a spacing between the first lower electrode Eb1 and the second lower electrode Eb2 may be defined as a second distance b.

The first and second lower electrodes Eb1 and Eb2 may be symmetrical with respect to a center C1b between them in the plan view, and the first and second upper electrodes Et1 and Et2 may be symmetrical with respect to a center C1t between them in the plan view.

The second spacing distance a between the first and second upper electrodes Et1 and Et2 in the first horizontal direction may vary depending on positions in a second horizontal direction, and the first spacing distance b between the first and second lower electrodes Eb1 and Eb2 in the first horizontal direction may vary depending on positions in the second horizontal direction different from the first horizontal direction.

Referring to FIG. 11 and FIG. 12, a variation pattern of a first spacing distance between the first lower electrode Eb1 and the second lower electrode Eb2 in a first horizontal direction may be opposite to a variation pattern of a second spacing distance between the first upper electrode Et1 and the second upper electrode Et2 in the first horizontal direction.

The first spacing distance between the first and second lower electrodes Eb1 and Eb2 in the first horizontal direction may decrease toward a central position C2 in a second horizontal direction.

The second spacing distance between the first and second upper electrodes Et1 and Et2 in the first horizontal direction may increase toward the central position C2 in the second horizontal direction. Thus, the variation pattern of the first spacing distance decreases as the variation pattern of the second spacing distance increases and vice versa.

The first lower electrode Eb1 may have a first point closest to the second lower electrode Eb2, and the second lower electrode Eb2 may have a second point closest to the first lower electrode Eb1.

The first lower electrode Eb1 may be symmetrical with respect to an imaginary line C2 connecting the first and second points, and the second lower electrode Eb2 may also be symmetrical with respect to the same imaginary line C2.

Referring to FIG. 11 and FIG. 12, in one example, the second upper electrode Et2 and the second lower electrode Eb2 may include: an overlapping region where the second upper electrode Et2 and the second lower electrode Eb2 overlap, a first non-overlapping region where the second upper electrode Et2 and the second lower electrode Eb2 do not overlap (e.g., non-overlapping), and a second non-overlapping region located opposite to the first non-overlapping region with respect to the overlapping region. The first non-overlapping region may have a first length in the second horizontal direction that is different from in the first horizontal direction, and the second non-overlapping region may have a second length in the second horizontal direction that is different from the first length.

In another example, the first upper electrode Et1 and the first lower electrode Eb1 may include an overlapping region where the first upper electrode Et1 and the first lower electrode Eb1 overlap, a first non-overlapping region where the first upper electrode Et1 and the first lower electrode Eb1 do not overlap, and a second non-overlapping region where the first upper electrode Et1 and the first lower electrode Eb1 also do not overlap and is located opposite to the first non-overlapping region with respect to the overlapping region. The first non-overlapping region may have a first length in a second horizontal direction that differs from a first horizontal direction, and the second non-overlapping region may have a second length in the second horizontal direction different from the first length.

Even if an error occurs during the process of connecting the first upper electrode Et1 and the second upper electrode Et2 to the first lower electrode Eb1 and the second lower electrode Eb2, a short circuit may not occur between the first lower electrode Eb1 and the first upper electrode Et1, and between the second lower electrode Eb2 and the second upper electrode Et2.

In the display panel 110 according to embodiments of the present disclosure, a first side may have a convex shape in a direction opposite to the first horizontal direction, a second side may have a convex shape in the first horizontal direction, a third side may have a convex shape in the first horizontal direction, and a fourth side may have a convex shape in a direction opposite to the first horizontal direction.

Referring to FIG. 11 and FIG. 12, the first lower electrode Eb1 may have a first side facing the second lower electrode Eb2, and the second lower electrode Eb2 may have a second side facing the first lower electrode Eb1. Each of the first and second sides may include a bent surface at one or more points.

The first upper electrode Et1 may have a third side facing the second upper electrode Et2, and the second upper electrode Et2 may have a fourth side facing the first upper electrode Et1. Each of the third and fourth sides may include a bent surface at one or more points.

Due to the short-circuit prevention electrode structure shown in FIG. 11 and FIG. 12, even if a misalignment occurs during the process of aligning and connecting the first and second upper electrodes Et1 and Et2 with the first and second lower electrodes Eb1 and Eb2, a short circuit may not occur between the first lower electrode Eb1 and the first upper electrode Et1, and between the second lower electrode Eb2 and the second upper electrode Et2.

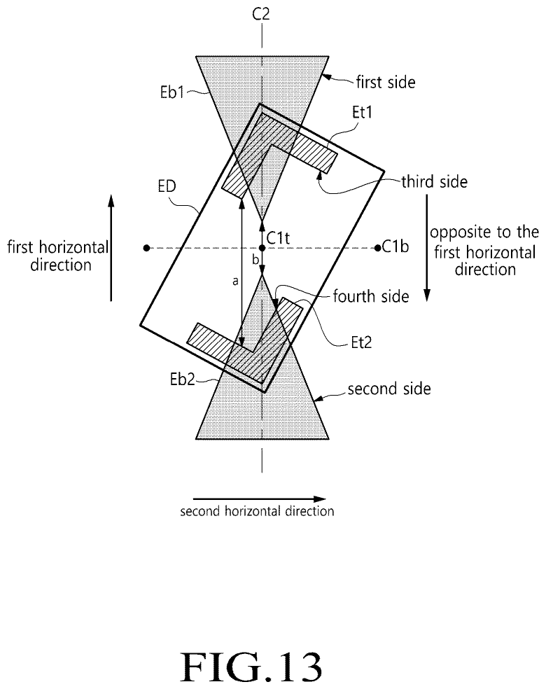

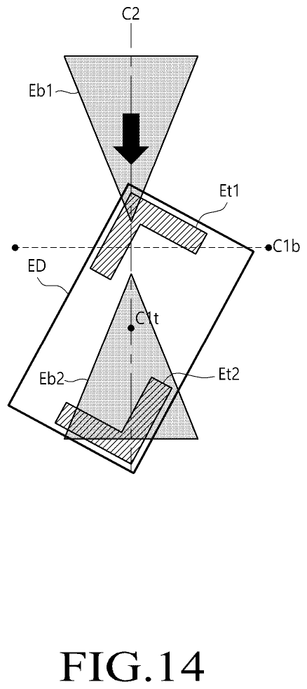

FIG. 13 and FIG. 14 are additional plan views illustrating another short-circuit prevention electrode structure of the display apparatus 100 according to embodiments of the present disclosure. FIG. 13 illustrates a case where no short circuit occurs due to a process error, and FIG. 14 illustrates a case where a short circuit occurs due to a process error.

Referring to FIG. 13 and FIG. 14, in the display apparatus 100 according to embodiments of the present disclosure, the display panel 110 may include a light emitting device ED disposed on a substrate. A region in which the light emitting device ED is disposed may include a first lower electrode Eb1, a second lower electrode Eb2, a first upper electrode Et1, and a second upper electrode Et2.

The second lower electrode Eb2 may be spaced apart from the first lower electrode Eb1 in a first horizontal direction and may be electrically connected to the second upper electrode Et2. The first lower electrode Eb1 may be electrically connected to the first upper electrode Et1. The second upper electrode Et2 may be spaced apart from the first upper electrode Et1 in the first horizontal direction and may be electrically connected to the second lower electrode Eb2.

The first lower electrode Eb1 may have an inverted triangular shape, and the second lower electrode Eb2 may have a triangular shape symmetrical to the first lower electrode Eb1.

The first upper electrode Et1 may have a shape rotated 45 degrees clockwise from an uppercase letter “L” with respect to virtual line C2 and the second upper electrode Et2 may have a shape symmetrical to the first upper electrode Et1. The light emitting device ED may have a shape rotated 45 degrees counterclockwise.

The first upper electrode Et1 may be disposed at a firstcorner of the light emitting device ED.

The second upper electrode Et2 may be disposed at a second corner of the light emitting device ED that is diagonally opposite to the first corner at which the first upper electrode Et1 is disposed.

A spacing between the first upper electrode Et1 and the second upper electrode Et2 may be defined as a first distance a, and a spacing between the first lower electrode Eb1 and the second lower electrode Eb2 may be defined as a second distance b.

The first lower electrode Eb1 and the second lower electrode Eb2 may be symmetrical with respect to a center C1b between them in the plan view, and the first upper electrode Et1 and the second upper electrode Et2 may be symmetrical with respect to a center C1t between them in the plan view.

A first spacing distance a between the first upper electrode Et1 and the second upper electrode Et2 in a first horizontal direction may vary depending on a position in a second horizontal direction, and a second spacing distance b between the first lower electrode Eb1 and the second lower electrode Eb2 in the first horizontal direction may also vary depending on a position in the second horizontal direction, which is different from the first horizontal direction.

The first lower electrode Eb1 may have a first point closest to the second lower electrode Eb2, and the second lower electrode Eb2 may have a second point closest to the first lower electrode Eb1.

The first lower electrode Eb1 may be symmetrical with respect to an imaginary line C2 connecting the first and second points, and the second lower electrode Eb2 may also be symmetrical with respect to the same imaginary line C2.

Referring to FIG. 13 and FIG. 14, in one example, the second upper electrode Et2 and the second lower electrode Eb2 may include an overlapping region where the second upper electrode Et2 and the second lower electrode Eb2 overlap, a first non-overlapping region where the second upper electrode Et2 and the second lower electrode Eb2 do not overlap (e.g., non-overlapping), and a second non-overlapping region which also does not involve any overlap between the second upper electrode Et2 and the second lower electrode Eb2, and is located opposite to the first non-overlapping region with respect to the overlapping region. The first non-overlapping region may have a first length in the second horizontal direction, and the second non-overlapping region may have a second length different from the first length.

In another example, the first upper electrode Et1 and the first lower electrode Eb1 may include an overlapping region where the first upper electrode Et1 and the first lower electrode Eb1 overlap, a first non-overlapping region where the first upper electrode Et1 and the first lower electrode Eb1 do not overlap (e.g., non-overlapping), and a second non-overlapping region, which also does not overlap between the first upper electrode Et1 and the first lower electrode Eb1, and is located opposite to the first non-overlapping region with respect to the overlapping region. The first non-overlapping region may have a first length in a second horizontal direction different from a first horizontal direction, and the second non-overlapping region may have a second length in the second horizontal direction, which is different from the first length.

In the display panel 110 according to embodiments of the present disclosure, a first side may have a convex shape in a direction opposite to the first horizontal direction, a second side may have a convex shape in the first horizontal direction, a third side may have a convex shape in the first horizontal direction, and a fourth side may have a convex shape in a direction opposite to the first horizontal direction.

Referring to FIG. 13 and FIG. 14, the first lower electrode Eb1 may have a first side facing the second lower electrode Eb2, and the second lower electrode Eb2 may have a second side facing the first lower electrode Eb1. Each of the first and second sides may include a bent surface at one or more points.

The first upper electrode Et1 may have a third side facing the second upper electrode Et2, and the second upper electrode Et2 may have a fourth side facing the first upper electrode Et1. Each of the third and fourth sides may include a bent surface at one or more points.

Due to the short-circuit prevention electrode structure shown in FIG. 13 and FIG. 14, even if an error occurs during the process of connecting the first upper electrode Et1 and the second upper electrode Et2 to the corresponding first lower electrode Eb1 and second lower electrode Eb2, a short circuit may not occur between the first lower electrode Eb1 and the first upper electrode Et1, and between the second lower electrode Eb2 and the second upper electrode Et2.

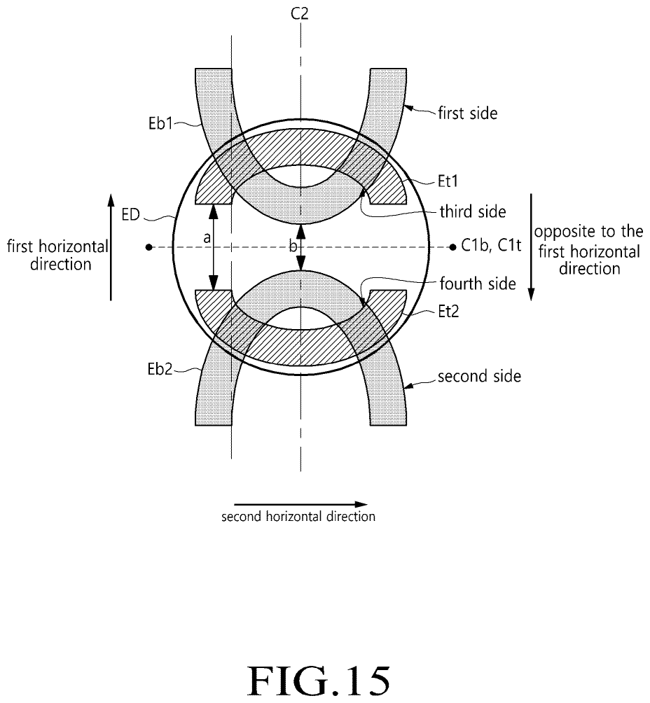

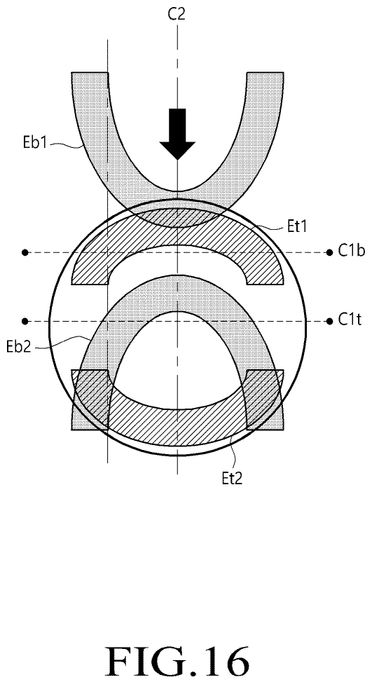

FIG. 15 and FIG. 16 are further plan views illustrating another short-circuit prevention electrode structure of the display apparatus 100 according to embodiments of the present disclosure. FIG. 15 illustrates a case without process error, and FIG. 16 illustrates a case where a process error occurs.

Referring to FIG. 15 and FIG. 16, in the display apparatus 100 according to embodiments of the present disclosure, the display panel 110 may include a light emitting device ED disposed on a substrate. A region in which the light emitting device ED is disposed may include the first lower electrode Eb1, the second lower electrode Eb2, the first upper electrode Et1, and the second upper electrode Et2.

The second lower electrode Eb2 may be spaced apart from the first lower electrode Eb1 in a first horizontal direction and may be electrically connected to the second upper electrode Et2. The first lower electrode Eb1 may be electrically connected to the first upper electrode Et1. The second upper electrode Et2 may be spaced apart from the first upper electrode Et1 in the first horizontal direction and may be electrically connected to the second lower electrode Eb2.

Referring to FIG. 15 and FIG. 16, the first lower electrode Eb1 may have a U-shape, and the second lower electrode Eb2 may have an inverted U-shape that is symmetrical to the first lower electrode Eb1. The first upper electrode Et1 may have an inverted U-shape, and the second upper electrode Et2 may have a shape symmetrical to the first upper electrode Et1.

The first lower electrode Eb1 and the second lower electrode Eb2 may be symmetrical with respect to a center C1b between them in the plan view, and the first upper electrode Et1 and the second upper electrode Et2 may be symmetrical with respect to a center C1t between them in the plan view.

A second spacing distance a between the first and second upper electrodes Et1 and Et2 in the first horizontal direction may vary depending on positions in a second horizontal direction, and a first spacing distance b between the first and second lower electrodes Eb1 and Eb2 may also vary depending on positions in the second horizontal direction.

Referring to FIG. 15 and FIG. 16, a variation pattern of the first spacing distance between the first and second lower electrodes Eb1 and Eb2 in the first horizontal direction may be opposite to a variation pattern of the second spacing distance between the first and second upper electrodes Et1 and Et2 in the first horizontal direction.

The first spacing distance between the first and second lower electrodes Eb1 and Eb2 in the first horizontal direction may decrease toward a central position C2 in the second horizontal direction.

The second spacing distance between the first and second upper electrodes Et1 and Et2 in the first horizontal direction may increase toward the central position C2 in the second horizontal direction. Thus, the variation pattern of the first spacing distance decreases as the variation pattern of the second spacing distance increases and vice versa.

The first lower electrode Eb1 may have a first point closest to the second lower electrode Eb2, and the second lower electrode Eb2 may have a second point closest to the first lower electrode Eb1.

The first lower electrode Eb1 may be symmetrical with respect to an imaginary line C2 connecting a first point and a second point, and the second lower electrode Eb2 may also be symmetrical with respect to the same imaginary line C2.

The first upper electrode Et1 may have a third point farthest from the second upper electrode Et2, and the second upper electrode Et2 may have a fourth point farthest from the first upper electrode Et1.

The first upper electrode Et1 may be symmetrical with respect to an imaginary line connecting the third and fourth points, and the second upper electrode Et2 may also be symmetrical with respect to the same imaginary line.

Referring to FIG. 15 and FIG. 16, in one example, the second upper electrode Et2 and the second lower electrode Eb2 may include an overlapping region where the second upper electrode Et2 and the second lower electrode Eb2 overlap, a first non-overlapping region where the second upper electrode Et2 and the second lower electrode Eb2 do not overlap (e.g., non-overlapping), and a second non-overlapping region which also does not overlap between the second upper electrode Et2 and the second lower electrode Eb2, and is located opposite to the first non-overlapping region with respect to the overlapping region. The first non-overlapping region may have a first length in a second horizontal direction different from a first horizontal direction, and the second non-overlapping region may have a second length in the second horizontal direction, which is different from the first length.

In another example, the first upper electrode Et1 and the first lower electrode Eb1 may include an overlapping region where the first upper electrode Et1 and the first lower electrode Eb1 overlap, a first non-overlapping region where the first upper electrode Et1 and the first lower electrode Eb1 do not overlap, and a second non-overlapping region, which also does not overlap between the first upper electrode Et1 and the first lower electrode Eb1, and is located opposite to the first non-overlapping region with respect to the overlapping region. The first non-overlapping region may have a first length in a second horizontal direction different from a first horizontal direction, and the second non-overlapping region may have a second length in the second horizontal direction, which is different from the first length.

In the display panel 110 according to embodiments of the present disclosure, a first side may have a convex shape in a direction opposite to the first horizontal direction, a second side may have a convex shape in the first horizontal direction, a third side may have a convex shape in the first horizontal direction, and a fourth side may have a convex shape in a direction opposite to the first horizontal direction.

The first lower electrode Eb1 may have a first side facing the second lower electrode Eb2, and the second lower electrode Eb2 may have a second side facing the first lower electrode Eb1. Each of the first and second sides may include a curved surface.

The first upper electrode Et1 may have a third side facing the second upper electrode Et2, and the second upper electrode Et2 may have a fourth side facing the first upper electrode Et1. Each of the third and fourth sides may include a curved surface.

Due to the short-circuit prevention electrode structure shown in FIG. 15 and FIG. 16, even if an error occurs during the process of connecting the first upper electrode Et1 to the first lower electrode Eb1 and the second upper electrode Et2 to the second lower electrode Eb2, a short circuit may not occur between the first lower electrode Eb1 and the first upper electrode Et1, and between the second lower electrode Eb2 and the second upper electrode Et2.

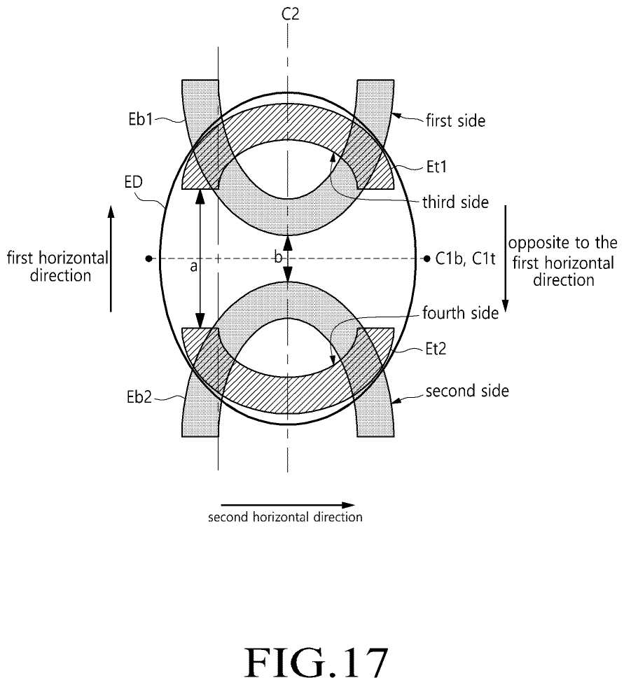

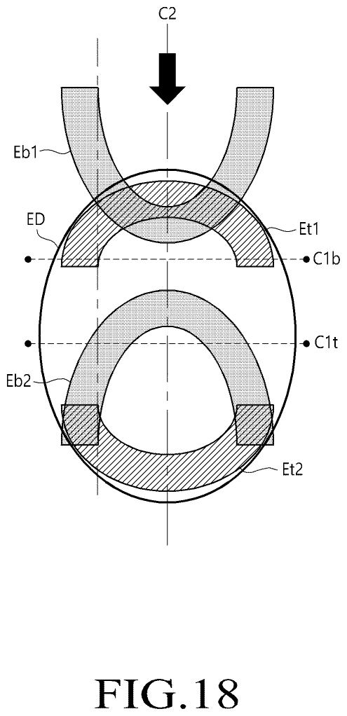

FIG. 17 and FIG. 18 are additional plan views illustrating a short-circuit prevention electrode structure of the display apparatus 100 according to embodiments of the present disclosure. FIG. 17 illustrates a case without process error, and FIG. 18 illustrates a case where a process error occurs.

Referring to FIG. 17 and FIG. 18, in the display apparatus 100 according to embodiments of the present disclosure, the display panel 110 may include a light emitting device ED disposed on a substrate. A region in which the light emitting device ED is disposed may include the first lower electrode Eb1, the second lower electrode Eb2, the first upper electrode Et1, and the second upper electrode Et2.

The second lower electrode Eb2 may be spaced apart from the first lower electrode Eb1 in a first horizontal direction and may be electrically connected to the second upper electrode Et2. The first lower electrode Eb1 may be electrically connected to the first upper electrode Et1. The second upper electrode Et2 may be spaced apart from the first upper electrode Et1 in the first horizontal direction and may be electrically connected to the second lower electrode Eb2.

Referring to FIG. 17 and FIG. 18, the first lower electrode Eb1 may have a U-shape, and the second lower electrode Eb2 may have a shape symmetrical to the first lower electrode Eb1. The first upper electrode Et1 may have an inverted U-shape, and the second upper electrode Et2 may have a shape symmetrical to the first upper electrode Et1.

The first lower electrode Eb1 and the second lower electrode Eb2 may be symmetrical with respect to a center C1b between them in the plan view, and the first upper electrode Et1 and the second upper electrode Et2 may be symmetrical with respect to a center C1t between them in the plan view.

A second spacing distance a between the first and second upper electrodes Et1 and Et2 in the first horizontal direction may vary depending on positions in the second horizontal direction, and a first spacing distance b between the first and second lower electrodes Eb1 and Eb2 may also vary depending on positions in the second horizontal direction that is different from the first horizontal direction.

Referring to FIG. 17 and FIG. 18, a variation pattern of the first spacing distance between the first and second lower electrodes Eb1 and Eb2 in the first horizontal direction may be opposite to a variation pattern of the second spacing distance between the first and second upper electrodes Et1 and Et2.

The first spacing distance between the first and second lower electrodes Eb1 and Eb2 in the first horizontal direction may decrease toward a central position C2 in the second horizontal direction.

The second spacing distance between the first and second upper electrodes Et1 and Et2 in the first horizontal direction may increase toward the central position C2 in the second horizontal direction. Thus, the variation pattern of the first spacing distance decreases as the variation pattern of the second spacing distance increases and vice versa.

The first lower electrode Eb1 may have a first point closest to the second lower electrode Eb2, and the second lower electrode Eb2 may have a second point closest to the first lower electrode Eb1.

The first lower electrode Eb1 may be symmetrical with respect to an imaginary line C2 connecting the first and second points, and the second lower electrode Eb2 may also be symmetrical with respect to the same imaginary line C2.

The first upper electrode Et1 may have a third point farthest from the second upper electrode Et2, and the second upper electrode Et2 may have a fourth point farthest from the first upper electrode Et1.

The first upper electrode Et1 may be symmetrical with respect to an imaginary line connecting the third and fourth points, and the second upper electrode Et2 may also be symmetrical with respect to the same imaginary line.

Referring to FIG. 17 and FIG. 18, in one example, the second upper electrode Et2 and the second lower electrode Eb2 may include an overlapping region where the second upper electrode Et2 and the second lower electrode Eb2 overlap, a first non-overlapping region where the second upper electrode Et2 and the second lower electrode Eb2 do not overlap, and a second non-overlapping region, which also does not overlap between the second upper electrode Et2 and the second lower electrode Eb2, and is located opposite to the first non-overlapping region with respect to the overlapping region. The first non-overlapping region may have a first length in a second horizontal direction different from a first horizontal direction, and the second non-overlapping region may have a second length in the second horizontal direction, which is different from the first length.

In another example, the first upper electrode Et1 and the first lower electrode Eb1 may include an overlapping region where the first upper electrode Et1 and the first lower electrode Eb1 overlap, a first non-overlapping region where the first upper electrode Et1 and the first lower electrode Eb1 do not overlap, and a second non-overlapping region, which also does not overlap between the first upper electrode Et1 and the first lower electrode Eb1, and is located opposite to the first non-overlapping region with respect to the overlapping region. The first non-overlapping region may have a first length in a second horizontal direction different from a first horizontal direction, and the second non-overlapping region may have a second length in the second horizontal direction, which is different from the first length.

In the display panel 110 according to embodiments of the present disclosure, a first side may have a convex shape in a direction opposite to the first horizontal direction, a second side may have a convex shape in the first horizontal direction, a third side may have a convex shape in the first horizontal direction, and a fourth side may have a convex shape in a direction opposite to the first horizontal direction.

The first lower electrode Eb1 may include a first side facing the second lower electrode Eb2, and the second lower electrode Eb2 may include a second side facing the first lower electrode Eb1. Each of the first and second sides may include a curved surface.

The first upper electrode Et1 may include a third side facing the second upper electrode Et2, and the second upper electrode Et2 may include a fourth side facing the first upper electrode Et1. Each of the third and fourth sides may include a curved surface.

Due to the short-circuit prevention electrode structure shown in FIG. 17 and FIG. 18, even if an error occurs during the process of connecting the first upper electrode Et1 to the first lower electrode Eb1 and the second upper electrode Et2 to the second lower electrode Eb2, a short circuit may not occur between the first lower electrode Eb1 and the first upper electrode Et1, and between the second lower electrode Eb2 and the second upper electrode Et2.

In one example, when transferring the light emitting device ED onto the first insulating layer 400, a short circuit may not occur between the first and second electrodes 410 and 420 and the first and second driving electrodes 401 and 402, even if a transfer process error occurs.

In another example, even if a process error occurs during the formation of the first and second driving electrodes, a short circuit may not occur between the first and second driving electrodes 301 and 302 and the first and second electrodes 310 and 320 of the light emitting device ED.

The first electrode 410 may be electrically connected only to the first driving electrode 401.

During panel fabrication, even if a transfer error occurs while transferring the light emitting device ED onto the first insulating layer 400, the first driving electrode 401 may be located on the first electrode 410 of the light emitting device ED, and the second driving electrode 402 may be located on the second electrode 420 of the light emitting device ED. Accordingly, the first driving electrode 401 may be electrically connected to the first electrode 410 of the light emitting device ED, and the second driving electrode 402 may be electrically connected to the second electrode 420 of the light emitting device ED.

Furthermore, even if a transfer process error occurs, the first electrode 410 of the light emitting device ED may be electrically connected to the first driving electrode 401 but not to the second driving electrode 402. Similarly, the second electrode 420 of the light emitting device ED may be electrically connected to the second driving electrode 402 but not to the first driving electrode 401. That is, a short circuit between electrodes may not occur even when a transfer error occurs.

In one example, the first and second upper electrodes Et1 and Et2 in FIG. 9 to FIG. 20 may correspond to the electrodes (e.g., anode and cathode electrodes) of the light emitting device ED. The first and second lower electrodes Eb1 and Eb2 in FIG. 9 to FIG. 20 may be electrodes formed on the substrate 111 and connected to the electrodes (e.g., anode and cathode electrodes) of the light emitting device ED. For instance, the first and second upper electrodes Et1 and Et2 in FIG. 9 to FIG. 20 may correspond to the first and second electrodes 310 and 320 of the light emitting device ED shown in FIG. 3, and the first and second lower electrodes Eb1 and Eb2 may correspond to the first and second driving electrodes 301 and 302 shown in FIG. 3.

In another example, the first and second lower electrodes Eb1 and Eb2 in FIG. 9 to FIG. 20 may correspond to the electrodes (e.g., anode and cathode electrodes) of the light emitting device ED, and the first and second upper electrodes Et1 and Et2 in FIGS. 9 to 20 may be electrodes formed on the substrate 111 and connected to the electrodes (e.g., anode and cathode electrodes) of the light emitting device ED. For instance, the first and second lower electrodes Eb1 and Eb2 in FIG. 9 to FIG. 20 may correspond to the first and second electrodes 410 and 420 shown in FIG. 4, and first and second upper electrodes Et1 and Et2 may correspond to the first and second driving electrodes 301 and 302 shown in FIG. 4.

Referring to FIG. 9 to FIG. 20, the first and second lower electrodes Eb1 and Eb2 may have a larger area than the first and second upper electrodes Et1 and Et2. However, this is merely an example for explanatory purposes and is not limited thereto. For example, the first lower electrode Eb1 and the second lower electrode Eb2 may have the same area as the first upper electrode Et1 and the second upper electrode Et2. The first lower electrode Eb1 and the second lower electrode Eb2 may also have a smaller area than the first upper electrode Et1 and the second upper electrode Et2.

The embodiments of the present disclosure described above may be summarized as follows.

In one embodiment, a display apparatus comprises: a substrate; and a light emitting device on the substrate, the light emitting device including a first upper electrode and a second upper electrode that is spaced apart from the first upper electrode in a first horizontal direction in a plan view of the display apparatus, wherein a region in which the light emitting device is disposed comprises: a first lower electrode on the substrate, the first lower electrode overlapping the first upper electrode of the light emitting device; and a second lower electrode on the substrate and spaced apart from the first lower electrode in the first horizontal direction in the plan view, the second lower electrode overlapping the second upper electrode of the light emitting device, wherein a first spacing distance between the first lower electrode and the second lower electrode in the first horizontal direction varies depending on positions along a second horizontal direction that is different from the first horizontal direction in a plan view of the display apparatus, wherein a second spacing distance between the first upper electrode and the second upper electrode in the first horizontal direction varies depending on positions along the second horizontal direction in the plan view, and wherein a variation pattern of the first spacing distance is opposite to a variation pattern of the second spacing distance.

In one embodiment, the first lower electrode and the second lower electrode are symmetrical with respect to a center between the first lower electrode and the second lower electrode in the plan view, and the first upper electrode and the second upper electrode are symmetrical with respect to a center between the first upper electrode and the second upper electrode in the plan view.

In one embodiment, the first upper electrode and the second upper electrode are electrodes of the light emitting device.

In one embodiment, the first lower electrode and the second lower electrode are driving electrodes of the light emitting device, the first lower electrode electrically connected to the first upper electrode but not the second upper electrode and the second lower electrode connected to the second upper electrode but not the first upper electrode.

In one embodiment, the first spacing distance between the first lower electrode and the second lower electrode in the first horizontal direction decreases toward a central position in the second horizontal direction in the plan view, and the second spacing distance between the first upper electrode and the second upper electrode in the first horizontal direction increases toward the central position in the second horizontal direction in the plan view.

In one embodiment, the first spacing distance between the first lower electrode and the second lower electrode in the first horizontal direction increases toward a central position in the second horizontal direction in the plan view and the second spacing distance between the first upper electrode and the second upper electrode in the first horizontal direction decreases toward the central position in the second horizontal direction in the plan view.

In one embodiment, the first lower electrode includes a first point closest to the second lower electrode and the second lower electrode includes a second point closest to the first lower electrode, wherein the first lower electrode is symmetrical with respect to an imaginary line connecting the first point and the second point in the plan view, and the second lower electrode is symmetrical with respect to the imaginary line connecting the first point and the second point in the plan view.

In one embodiment, the first upper electrode includes a third point farthest from the second upper electrode and the second upper electrode includes a fourth point farthest from the first upper electrode, wherein the first upper electrode is symmetrical with respect to an imaginary line connecting the third point and the fourth point in the plan view, and the second upper electrode is symmetrical with respect to the imaginary line connecting the third point and the fourth point in the plan view.

In one embodiment, the first lower electrode has a convex side in the first horizontal direction, the first upper electrode has a concave side in the first horizontal direction, the second lower electrode has a concave side in the first horizontal direction, and the second upper electrode has a convex side in the first horizontal direction.

In one embodiment, the first lower electrode includes a first side facing the second lower electrode, the second lower electrode includes a second side facing the first lower electrode, and each of the first side and the second side includes a bent surface at one or more points.

In one embodiment, the first lower electrode includes a first side facing the second lower electrode, the second lower electrode includes a second side facing the first lower electrode, and each of the first side and the second side includes a curved surface.

In one embodiment, the first upper electrode includes a third side facing the second upper electrode, the second upper electrode includes a fourth side facing the first upper electrode, and each of the third side and the fourth side includes at least one bent or curved surface.

In one embodiment, the second upper electrode and the second lower electrode comprise an overlapping region where the second upper electrode and the second lower electrode overlap each other in the plan view, a first non-overlapping region where the second upper electrode and the second lower electrode are non-overlapping with each other in the plan view, the first non-overlapping region at a first side of the overlapping region in the plan view, and a second non-overlapping region where the second upper electrode and the second lower electrode are non-overlapping with each other in the plan view, the second non-overlapping region at a second side of the overlapping region that is opposite to the first side in the plan view, wherein the first non-overlapping region has a first length in a second horizontal direction that is different from the first horizontal direction and the second non-overlapping region has a second length in the second horizontal direction that is different from the first length.

In one embodiment, the first upper electrode and the first lower electrode comprise an overlapping region where the first upper electrode and the first lower electrode overlap each other in the plan view, a first non-overlapping region where the first upper electrode and the first lower electrode are non-overlapping with each other in the plan view, the first non-overlapping region at a first side of the overlapping region in the plan view, and a second non-overlapping region where the first upper electrode and the first lower electrode are non-overlapping with each other in the plan view, the second non-overlapping region at a second side of the overlapping region that is opposite to the first side in the plan view, wherein the first non-overlapping region has a first length in a second horizontal direction that is different from the first horizontal direction and the second non-overlapping region has a second length in the second horizontal direction that is different from the first length.

In one embodiment, the first lower electrode has an inverted triangular shape in the plan view and the second lower electrode has a triangular shape that is symmetrical to the first lower electrode in the plan view.

In one embodiment, the first lower electrode has a U-shape in the plan view and the second lower electrode has an inverted U-shape that is symmetrical to the first lower electrode.

In one embodiment, a display apparatus comprises: a substrate; and a light emitting device on the substrate, wherein a region in which the light emitting device is disposed comprises: a first lower electrode on the substrate; a second lower electrode on the substrate and spaced apart from the first lower electrode in a first horizontal direction in a plan view of the display apparatus; a first upper electrode electrically connected to the first lower electrode; and a second upper electrode spaced apart from the first upper electrode in the first horizontal direction in the plan view, the second upper electrode electrically connected to the second lower electrode, wherein the first lower electrode and the second lower electrode are symmetrical with respect to a center between the first lower electrode and the second lower electrode in the plan view, and wherein the first upper electrode and the second upper electrode are symmetrical with respect to a center between the first upper electrode and the second upper electrode in the plan view, wherein the first lower electrode includes a first side facing the second lower electrode and the second lower electrode includes a second side facing the first lower electrode in the plan view, wherein the first upper electrode includes a third side facing the second upper electrode and the second upper electrode includes a fourth side facing the first upper electrode in the plan view, wherein the first side has a convex shape in a direction opposite to the first horizontal direction and the second side has a convex shape in the first horizontal direction in the plan view, and wherein the third side has a convex shape in the first horizontal direction and the fourth side has a convex shape in a direction opposite to the first horizontal direction in the plan view.

In one embodiment, a first spacing distance between the first lower electrode and the second lower electrode in the first horizontal direction decreases toward the center of the first lower electrode and the second lower electrode in the plan view, and a second spacing distance between the first upper electrode and the second upper electrode in the first horizontal direction increases toward the center of the first upper electrode and the second upper electrode in the plan view.

In one embodiment, a first spacing distance between the first lower electrode and the second lower electrode in the first horizontal direction increases toward the center of the first lower electrode and the second lower electrode in the plan view, and a second spacing distance between the first upper electrode and the second upper electrode in the first horizontal direction decreases toward the center between the first upper electrode and the second upper electrode in the plan view.

In one embodiment, the first upper electrode and the second upper electrode correspond to electrodes of the light emitting device or the first lower electrode and the second lower electrode correspond to electrodes of the light emitting device.

In one embodiment, a display apparatus comprises: a substrate; a plurality of lower electrodes on the substrate, the plurality of lower electrodes including a first lower electrode and a second lower electrode that are symmetrical to each other in a plan view of the display apparatus with respect to a point between the first lower electrode and the second lower electrode; and a plurality of upper electrodes on the substrate, the plurality of upper electrodes including: a first upper electrode that is electrically connected to the first lower electrode, the first upper electrode including a first portion that overlaps the first lower electrode and at least one second portion that is non-overlapping with the first lower electrode in the plan view; and a second upper electrode that is electrically connected to the second lower electrode, the second upper electrode including a first portion that overlaps the second lower electrode and at least one second portion that is non-overlapping with the second lower electrode in the plan view, wherein the first upper electrode and the second upper electrode are symmetrical to each other in the plan view with respect to a point between the first upper electrode and the second upper electrode.

In one embodiment, the first upper electrode and the second upper electrode are included in a light emitting device or the first lower electrode and the second lower electrode are included in the light emitting device.

In one embodiment, the first lower electrode and the second lower electrode each have a triangular shape in the plan view and the first upper electrode and the second upper electrode each have a “V” shape in the plan view.

In one embodiment, the first lower electrode and the second lower electrode each have a triangular shape in the plan view, and each of the first upper electrode and the second upper electrode has a first horizontal portion extending in a horizontal direction in the plan view and a first vertical portion extending from a first end of the first horizontal portion in a vertical direction in the plan view and a second vertical portion extending from a second end of the first horizontal portion in the vertical direction in the plan view.

In one embodiment, the first lower electrode and the second lower electrode each have a first curved shape in the plan view and the first upper electrode and the second upper electrode each have a second curved shape in the plan view.

According to embodiments of the present disclosure, a display apparatus may be provided that includes a robust structure (short-circuit prevention structure) resistant to process errors during the fabrication of a high-resolution display panel including a miniaturized light emitting device.

According to embodiments of the present disclosure, during a panel fabrication process for connecting electrodes of a light emitting device (e.g., an anode and a cathode) with electrodes formed on a substrate of a display panel (e.g., an anode and a cathode), the display apparatus may include a short-circuit prevention structure that can prevent abnormal electrical connections (e.g., short-circuiting between the anode of the light emitting device and the cathode of the panel).

According to embodiments of the present disclosure, during a panel fabrication process involving transfer of the light emitting device onto the display panel, the display apparatus may include a short-circuit prevention structure that can prevent abnormal connections (e.g., a short between the anode of the light emitting device and the cathode on the substrate) caused by process errors.

According to embodiments of the present disclosure, a display apparatus may reduce defective products caused by process errors during panel manufacturing, thereby enabling process optimization and contributing to yield improvement and reduction of greenhouse gas emissions.

The above description has been presented to enable any person skilled in the art to make and use the technical idea of the present invention, and has been provided in the context of a particular application and its requirements. Various modifications, additions, and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

### DESCRIPTION OF REFERENCE NUMERALS

100: display apparatus
110: display panel
120: gate driver
130: data driver
140: controller

What is claimed is:

1. A display apparatus comprising:
a substrate; and
a light emitting device on the substrate, the light emitting device including a first upper electrode and a second upper electrode that is spaced apart from the first upper electrode in a first horizontal direction in a plan view of the display apparatus,
wherein a region in which the light emitting device is disposed comprises:
a first lower electrode on the substrate, the first lower electrode overlapping the first upper electrode of the light emitting device; and
a second lower electrode on the substrate and spaced apart from the first lower electrode in the first horizontal direction in the plan view, the second lower electrode overlapping the second upper electrode of the light emitting device,
wherein a first spacing distance between the first lower electrode and the second lower electrode in the first horizontal direction varies depending on positions along a second horizontal direction that is different from the first horizontal direction in a plan view of the display apparatus,
wherein a second spacing distance between the first upper electrode and the second upper electrode in the first horizontal direction varies depending on positions along the second horizontal direction in the plan view, and
wherein a variation pattern of the first spacing distance is opposite to a variation pattern of the second spacing distance.

2. The display apparatus of claim 1, wherein the first lower electrode and the second lower electrode are symmetrical with respect to a center between the first lower electrode and the second lower electrode in the plan view, and
wherein the first upper electrode and the second upper electrode are symmetrical with respect to a center between the first upper electrode and the second upper electrode in the plan view.

3. The display apparatus of claim 1, wherein the first upper electrode and the second upper electrode are electrodes of the light emitting device.

4. The display apparatus of claim 1, wherein the first lower electrode and the second lower electrode are driving electrodes of the light emitting device, the first lower electrode electrically connected to the first upper electrode but not the second upper electrode and the second lower electrode connected to the second upper electrode but not the first upper electrode.

5. The display apparatus of claim 1, wherein the first spacing distance between the first lower electrode and the second lower electrode in the first horizontal direction decreases toward a central position in the second horizontal direction in the plan view, and
wherein the second spacing distance between the first upper electrode and the second upper electrode in the first horizontal direction increases toward the central position in the second horizontal direction in the plan view.

6. The display apparatus of claim 1, wherein the first spacing distance between the first lower electrode and the second lower electrode in the first horizontal direction increases toward a central position in the second horizontal direction in the plan view and the second spacing distance between the first upper electrode and the second upper electrode in the first horizontal direction decreases toward the central position in the second horizontal direction in the plan view.

7. The display apparatus of claim 1, wherein the first lower electrode includes a first point closest to the second lower electrode and the second lower electrode includes a second point closest to the first lower electrode,
wherein the first lower electrode is symmetrical with respect to an imaginary line connecting the first point and the second point in the plan view, and the second lower electrode is symmetrical with respect to the imaginary line connecting the first point and the second point in the plan view.

8. The display apparatus of claim 1, wherein the first upper electrode includes a third point farthest from the second upper electrode and the second upper electrode includes a fourth point farthest from the first upper electrode,
wherein the first upper electrode is symmetrical with respect to an imaginary line connecting the third point and the fourth point in the plan view, and the second upper electrode is symmetrical with respect to the imaginary line connecting the third point and the fourth point in the plan view.

9. The display apparatus of claim 1, wherein the first lower electrode has a convex side in the first horizontal direction, the first upper electrode has a concave side in the first horizontal direction, the second lower electrode has a concave side in the first horizontal direction, and the second upper electrode has a convex side in the first horizontal direction.

10. The display apparatus of claim 1, wherein the first lower electrode includes a first side facing the second lower electrode, the second lower electrode includes a second side facing the first lower electrode, and each of the first side and the second side includes a bent surface at one or more points.

11. The display apparatus of claim 1, wherein the first lower electrode includes a first side facing the second lower electrode, the second lower electrode includes a second side facing the first lower electrode, and each of the first side and the second side includes a curved surface.

12. The display apparatus of claim 1, wherein the first upper electrode includes a third side facing the second upper electrode, the second upper electrode includes a fourth side facing the first upper electrode, and each of the third side and the fourth side includes at least one bent or curved surface.

13. The display apparatus of claim 1, wherein the second upper electrode and the second lower electrode comprise:
an overlapping region where the second upper electrode and the second lower electrode overlap each other in the plan view;
a first non-overlapping region where the second upper electrode and the second lower electrode are non-overlapping with each other in the plan view, the first non-overlapping region at a first side of the overlapping region in the plan view; and
a second non-overlapping region where the second upper electrode and the second lower electrode are non-overlapping with each other in the plan view, the second non-overlapping region at a second side of the overlapping region that is opposite to the first side in the plan view,
wherein the first non-overlapping region has a first length in a second horizontal direction that is different from the first horizontal direction and the second non-overlapping region has a second length in the second horizontal direction that is different from the first length.

14. The display apparatus of claim 1, wherein the first upper electrode and the first lower electrode comprise:
an overlapping region where the first upper electrode and the first lower electrode overlap each other in the plan view;
a first non-overlapping region where the first upper electrode and the first lower electrode are non-overlapping with each other in the plan view, the first non-overlapping region at a first side of the overlapping region in the plan view; and
a second non-overlapping region where the first upper electrode and the first lower electrode are non-overlapping with each other in the plan view, the second non-overlapping region at a second side of the overlapping region that is opposite to the first side in the plan view,
wherein the first non-overlapping region has a first length in a second horizontal direction that is different from the first horizontal direction and the second non-overlapping region has a second length in the second horizontal direction that is different from the first length.

15. The display apparatus of claim 1, wherein the first lower electrode has an inverted triangular shape in the plan view and the second lower electrode has a triangular shape that is symmetrical to the first lower electrode in the plan view.

16. The display apparatus of claim 1, wherein the first lower electrode has a U-shape in the plan view and the second lower electrode has an inverted U-shape that is symmetrical to the first lower electrode.

17. A display apparatus comprising:
a substrate; and
a light emitting device on the substrate, wherein a region in which the light emitting device is disposed comprises:
a first lower electrode on the substrate;
a second lower electrode on the substrate and spaced apart from the first lower electrode in a first horizontal direction in a plan view of the display apparatus;
a first upper electrode electrically connected to the first lower electrode; and
a second upper electrode spaced apart from the first upper electrode in the first horizontal direction in the plan view, the second upper electrode electrically connected to the second lower electrode,
wherein the first lower electrode and the second lower electrode are symmetrical with respect to a center between the first lower electrode and the second lower electrode in the plan view, and
wherein the first upper electrode and the second upper electrode are symmetrical with respect to a center between the first upper electrode and the second upper electrode in the plan view,
wherein the first lower electrode includes a first side facing the second lower electrode and the second lower electrode includes a second side facing the first lower electrode in the plan view,
wherein the first upper electrode includes a third side facing the second upper electrode and the second upper electrode includes a fourth side facing the first upper electrode in the plan view,
wherein the first side has a convex shape in a direction opposite to the first horizontal direction and the second side has a convex shape in the first horizontal direction in the plan view,
wherein the third side has a convex shape in the first horizontal direction and the fourth side has a convex shape in a direction opposite to the first horizontal direction in the plan view.

18. The display apparatus of claim 17, wherein a first spacing distance between the first lower electrode and the second lower electrode in the first horizontal direction decreases toward the center of the first lower electrode and the second lower electrode in the plan view, and a second spacing distance between the first upper electrode and the second upper electrode in the first horizontal direction increases toward the center of the first upper electrode and the second upper electrode in the plan view.

19. The display apparatus of claim 17, wherein a first spacing distance between the first lower electrode and the second lower electrode in the first horizontal direction increases toward the center of the first lower electrode and the second lower electrode in the plan view, and a second spacing distance between the first upper electrode and the second upper electrode in the first horizontal direction decreases toward the center between the first upper electrode and the second upper electrode in the plan view.

20. The display apparatus of claim 17, wherein the first upper electrode and the second upper electrode correspond to electrodes of the light emitting device or the first lower electrode and the second lower electrode correspond to electrodes of the light emitting device.

21. A display apparatus comprising:
a substrate;
a plurality of lower electrodes on the substrate, the plurality of lower electrodes including a first lower electrode and a second lower electrode that are symmetrical to each other in a plan view of the display apparatus with respect to a point between the first lower electrode and the second lower electrode;
a plurality of upper electrodes on the substrate, the plurality of upper electrodes including:
a first upper electrode that is electrically connected to the first lower electrode, the first upper electrode including a first portion that overlaps the first lower electrode and at least one second portion that is non-overlapping with the first lower electrode in the plan view; and
a second upper electrode that is electrically connected to the second lower electrode, the second upper electrode including a first portion that overlaps the second lower electrode and at least one second portion that is non-overlapping with the second lower electrode in the plan view,
wherein the first upper electrode and the second upper electrode are symmetrical to each other in the plan view with respect to a point between the first upper electrode and the second upper electrode.

22. The display apparatus of claim 21, wherein the first upper electrode and the second upper electrode are included in a light emitting device or the first lower electrode and the second lower electrode are included in the light emitting device.

23. The display apparatus of claim 21, wherein the first lower electrode and the second lower electrode each have a triangular shape in the plan view and the first upper electrode and the second upper electrode each have a “V” shape in the plan view.

24. The display apparatus of claim 21, wherein the first lower electrode and the second lower electrode each have a triangular shape in the plan view, and each of the first upper electrode and the second upper electrode has a first horizontal portion extending in a horizontal direction in the plan view and a first vertical portion extending from a first end of the first horizontal portion in a vertical direction in the plan view and a second vertical portion extending from a second end of the first horizontal portion in the vertical direction in the plan view.

25. The display apparatus of claim 21, wherein the first lower electrode and the second lower electrode each have a first curved shape in the plan view and the first upper electrode and the second upper electrode each have a second curved shape in the plan view.
